(19) United States
(12) Patent Application Publication
(10) Pub. No.: US 2013/0292800 A1
(43) Pub. Date: Nov. 7, 2013

(54) PROCESSES FOR PREPARING COPPER INDIUM GALLIUM SULFIDE/SELENIDE FILMS

(71) Applicants: Yanyan Cao, Wilmington, DE (US); Jonathan V. Caspar, Wilmington, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(72) Inventors: Yanyan Cao, Wilmington, DE (US); Jonathan V. Caspar, Wilmington, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(73) Assignee: E I DU PONT DE NEMOURS AND COMPANY, Wilmington, DE (US)

(21) Appl. No.: 13/988,406

(22) PCT Filed: Dec. 1, 2011
(86) PCT No.: PCT/US11/62877

§ 371 Date: May 20, 2013

Related U.S. Application Data
(60) Provisional application No. 61/419,371, filed on Dec. 3, 2010.
(60) Provisional application No. 61/419,373, filed on Dec. 3, 2010.

(51) Int. Cl. H01L 29/24

(52) U.S. Cl. CPC H01L 29/24
USPC 257/613; 438/483; 252/512; 252/519.14

(57) ABSTRACT

This invention relates to processes for preparing films of copper indium gallium sulfide/selenides (CIGS/Se) on substrates via inks comprising CIGS/Se microparticles and a plurality of particles. This invention relates to inks, coated layers, and film compositions. Such films are useful in the preparation of photovoltaic devices. This invention also relates to processes for preparing coated substrates and for making photovoltaic devices.

This application claims the benefit of U.S. Provisional Application No. 61/419,371, filed Dec. 3, 2010 and U.S. Provisional Application No. 61/419,373, filed Dec. 3, 2010 which are herein incorporated by reference.

### FIELD OF THE INVENTION

This invention relates to processes for preparing films of copper indium gallium sulfide/selenides (CIGS/Se) on substrates via inks comprising CIGS/Se microparticles and a plurality of particles. This invention relates to inks, coated layers, and film compositions. Such films are useful in the preparation of photovoltaic devices. This invention also relates to processes for preparing coated substrates and for making photovoltaic devices.

### BACKGROUND

Semiconductors with a composition of Cu(In_{y}Ga_{1-y})(SₓSe₂₋ₓ) where O<y≦1 and 0≦x≦2, collectively known as copper indium gallium sulfide/selenide or CIGS/Se, are some of the most promising candidates for thin-film photovoltaic applications due to their unique structural and electrical properties as energy absorber materials. However, current vacuum-based techniques to make CIGS/Se thin films (e.g., thermal evaporation, sputtering) require complicated equipment and therefore tend to be expensive. In addition, materials are wasted by deposition on chamber walls, and significant energy is required to evaporate or sputter materials from a source, often onto a heated substrate.

In contrast, solution-based processes to CIGS/Se are not only less expensive than vacuum-based processes, but typically have lower energy input and can utilize close to 100% of the raw materials by precisely and directly depositing materials on a substrate. In addition, solution-based processes are readily adaptable to high-throughput roll-to-roll processing on flexible substrates.

Solution-based processes to CIGS/Se fall into three general categories: (1) Electro-, electroless and chemical bath deposition where (electro)chemical reactions in a solution lead to the coating of an immersed substrate; (2) Particulate-based processes that use solid particles dispersed in a solvent to form an ink, which can be coated onto a substrate; and (3) Processes that coat molecular precursor solutions onto a substrate by mechanical means such as spraying or spin-coating.

Many of the routes to CIGS/Se rely on annealing in a reducing H₂, H₂₅, S-, or Se-containing atmosphere for chalcogenization and obtaining suitable grain size. Others rely on salt-based precursors (e.g., chlorides, nitrates), which can lead to chlorine- or oxygen-based impurities in the CIGS/Se film. A molecular precursor approach to CIGS/Se involving the preparation of a solution of copper and indium chalcogenides and elemental chalcogen has been reported. However, the use of hydrazine as the solvent was required. Hydrazine is a highly reactive and potentially explosive solvent that is described in the Merck Index as a “violent poison.” Single-source organometallic precursors to CIS/Se [e.g., (Ph₃P)₂Cu(mu-SEt)₂In(SEt)₂] have been prepared and used to form CIS/Se films via spray chemical vapor deposition. However, the synthesis of these single-source precursors is involved and limits the compositional tuning of film stoichiometry. In situ synthesis of films of CIS nanocrystals has been achieved by spin-coating butylamine solutions of indium acetate, copper chloride, thiourea, and propionic acid onto a substrate and heating at 250° C. Broad lines in the x-ray diffraction (XRD) analysis confirmed the nanocrystalline nature of the film.

Hence, there still exists a need for routes to CIGS/Se that involve simple, low-cost, scalable materials and processes with a low number of operations that provide high-quality, crystalline CIGS/Se films with tunable composition and morphology. There also exists a need for low-temperature routes to CIGS/Se using solvents and reagents with relatively low toxicity. In addition, there is a need for inks and processes to CIGS/Se that do not require annealing in a reducing H₂, H₂S, S-, or Se-containing atmosphere, and for inks that can be coated in a single coating operation to give films of suitable thickness for thin-film photovoltaic devices.

### SUMMARY

One aspect of this invention is an ink comprising:
(a) a plurality of CIGS/Se microparticles;
(b) a plurality of particles selected from the group consisting of:
   CIGS/Se nanoparticles; elemental Cu-, In-, or Ga-containing particles; binary or ternary Cu-, In-, or Ga-containing chalcogenide particles; and mixtures thereof; and
(c) a vehicle.

Another aspect of this invention is a process comprising disposing an ink onto a substrate to form a coated substrate, wherein the ink comprises:
(a) a plurality of CIGS/Se microparticles;
(b) a plurality of particles selected from the group consisting of:
   CIGS/Se nanoparticles; elemental Cu-, In-, or Ga-containing particles; binary or ternary Cu-, In-, or Ga-containing chalcogenide particles; and mixtures thereof; and
   (c) a vehicle.

Another aspect of this invention is a coated substrate comprising:
(a) a substrate; and
(b) at least one layer disposed on the substrate comprising:
   (i) a plurality of CIGS/Se microparticles; and
   (ii) a plurality of particles selected from the group consisting of:
      CIGS/Se nanoparticles; elemental Cu-, In-, or Ga-containing particles; binary or ternary Cu-, In-, or Ga-containing chalcogenide particles; and mixtures thereof.

Another aspect of this invention is a film comprising:
(a) an inorganic matrix; and
(b) CIGS/Se microparticles characterized by an average longest dimension of 0.5-200 microns, wherein the microparticles are embedded in the inorganic matrix.

Another aspect of this invention is a photovoltaic cell comprising the film as described above.

Another aspect of this invention is a process for producing a photovoltaic cell.

### DETAILED DESCRIPTION

Herein, the terms “solar cell” and “photovoltaic cell” are synonymous unless specifically defined otherwise. These terms refer to devices that use semiconductors to convert visible and near-visible light energy into usable electrical energy. The terms “band gap energy,” “optical band gap,” and “band gap” are synonymous unless specifically defined otherwise. These terms refer to the energy required to generate electron-hole pairs in a semiconductor material, which in general is the minimum energy needed to excite an electron from the valence band to the conduction band.

Monograin layer (MGL) solar cells are a subclass of solar cells, and are also known as monocrystalline and monoparticle membrane solar cells. The MGL consists of monograin powder crystals embedded in an organic resin. A main technological advantage is that the absorber is fabricated separately from the solar cell, which leads to benefits in both the absorber- and cell-stages of MGL solar cell production. High temperatures are often preferred in adsorber material production, while lower temperatures are often preferred in the cell production. Fabricating the absorber and then embedding it in a matrix allows the possibility of using inexpensive, flexible, low-temperature substrates in the manufacture of inexpensive flexible solar cells.

Herein, an inorganic matrix replaces the organic matrix used in traditional MGL solar cells. As defined herein, “inorganic matrix” refers to a matrix comprising inorganic semiconductors, precursors to inorganic semiconductors, inorganic insulators, precursors to inorganic insulators, or mixtures thereof. Materials designated as inorganic matrixes can also contain small amounts of other materials, including dopants such as sodium, and organic materials. Examples of suitable inorganic matrixes include Cu(In,Ga)(S,Se)₂, Cu₂ZnSn(S,Se)₄, SiO₂, and precursors thereof. The inorganic matrix is used in combination with microparticles of chalcogenide semiconductor to build a coated film. In some embodiments, the bulk of the functionality comes from the microparticles, and the inorganic matrix plays a role in layer formation and enhancement of the layer performance. The longest dimension of the microparticles can be greater than the average thickness of the inorganic matrix and, in some instances, can span the coated thickness. The longest dimension of the microparticles can be less than or equivalent to the coated thickness, resulting in a film with completely or partially embedded microparticles. The microparticles and inorganic matrix can comprise different materials or can consist of essentially the same composition or can vary in composition, e.g., the chalcogenide or dopant composition can vary.

Herein, grain size refers to the diameter of a grain of granular material, wherein the diameter is defined as the longest distance between two points on its surface. In contrast, crystallite size is the size of a single crystal inside the grain. A single grain can be composed of several crystals. Herein, a useful method for obtaining grain size is electron microscopy. ASTM test methods are available for determining planar grain size, that is, characterizing the two-dimensional grain sections revealed by the sectioning plane. Manual grain size measurements are described in ASTM E 112 (equiaxed grain structures with a single size distribution) and E 1182 (specimens with a bi-modal grain size distribution), while ASTM E 1382 describes how any grain size type or condition can be measured using image analysis methods.

Herein, element groups are represented using CAS notation. As used herein, the term “chalcogen” refers to Group VIA elements, and the terms “metal chalcogenides” or “chalcogenides” refer to materials that comprise metals and Group VIA elements. Suitable Group VIA elements include sulfur, selenium and tellurium. Metal chalcogenides are important candidate materials for photovoltaic applications, since many of these compounds have optical band gap values well within the terrestrial solar spectra.

Herein, the term “binary-metal chalcogenide” refers to a chalcogenide composition comprising one metal. The term “ternary-metal chalcogenide” refers to a chalcogenide composition comprising two metals. The term “quaternary-metal chalcogenide” refers to a chalcogenide composition comprising three metals. The term “multinary-metal chalcogenide” refers to a chalcogenide composition comprising two or more metals, and encompasses ternary and quaternary metal chalcogenide compositions.

Herein, the terms “copper indium sulfide” and “CIS” refer to CuInS₂. “Copper indium selenide” and “CISe” refer to CuInSe₂. “Copper indium sulfide/selenide,” “CIS/Se,” and “CIS—Se” encompass all possible combinations of CuIn(S,Se)₂, including CuInS₂, CuInSe₂, and CuInSₓSe₂₋ₓ, where 0≦x≦2. Herein, the terms “copper indium gallium sulfide/selenide” and “CIGS/Se” and “GIGS—Se” encompass all possible combinations of Cu(In_{y}Ga_{1-y})(SₓSe₂₋ₓ) where O<y≦1 and 0≦x≦2. The terms “CIS,” “CISe,” “CIS/Se,” and “CIGS/Se” further encompass copper indium gallium sulfide/selenide semiconductors with fractional stoichiometries, e.g., Cu_{0.7}In_{1.1}S₂. That is, the stoichiometry of the elements can vary from a strictly 1:1:2 molar ratio for Cu:(In+Ga):(S+Se). Materials designated as CIGS/Se can also contain small amounts of other elements such as sodium. In addition, the Cu and In in CIS/Se and CIGS/Se can be partially substituted by other metals. That is, Cu can be partially replaced by Ag and/or Au, and In by B, Al, and/or Tl. Highly efficient CIGS/Se solar cells are often copper-poor, that is the molar ratio of Cu:(In+Ga) is less than one.

As used herein, “coherent domain size” refers to the size of crystalline domains over which a defect-free, coherent structure exists. The coherency comes from the fact that the three-dimensional ordering is not broken inside of these domains. When the coherent grain size is less than about 100 nm, appreciable broadening of the x-ray diffraction lines will occur. The domain size can be estimated by measuring the full width at half maximum intensity of the diffraction peak.

Herein, the terms “nanoparticle,” “nanocrystal,” and “nanocrystalline particle” are synonymous unless specifically defined otherwise, and are meant to include nanoparticles with a variety of shapes that are characterized by an average longest dimension of about 1 nm to about 500 nm. Herein, by nanoparticle “size” or “size range” or “size distribution,” we mean that the average longest dimension of a plurality of nanoparticles falls within the range. “Longest dimension” is defined herein as the measurement of a nanoparticle from end to end. The “longest dimension” of a particle will depend on the shape of the particle. For example, for particles that are roughly or substantially spherical, the longest dimension will be a diameter of the particle. For other particles, the longest dimension will be a diagonal or a side.

Herein, the terms “microparticle,” “microcrystal,” and “microcrystalline particle” are synonymous unless specifically defined otherwise and are meant to include microparticles with a variety of shapes that are characterized by an average longest dimension of at least about 0.5 microns to about 200 microns. Herein, microparticle “size” or “size range” or “size distribution” are defined the same as described above for nanoparticles.

As defined herein, “coated particles” refers to particles that have a surface coating of organic or inorganic material. Methods for surface-coating inorganic particles are well-known in the art. As defined herein, the terms “surface coating” and “capping agent” are used synonymously and refer to a strongly absorbed or chemically bonded monolayer of organic or inorganic molecules on the surface of the particle(s). In addition to carbon and hydrogen, suitable organic capping agents can comprise functional groups, including nitrogen-, oxygen-, sulfur-, selenium-, or phosphorus-based functional groups. Suitable inorganic capping agents can comprise chalcogenides, including metal chalcogenides, or zintl ions, wherein zintl ions refers to homopolyatomic anions and heteropolyatomic anions that have intermetallic bonds between the same or different metals of the main group, transition metals, lanthanides, and/or actinides.

Elemental and metal chalcogenide particles can be composed only of the specified elements or can be doped with small amounts of other elements. As used herein, the term “alloy” refers to a substance that is a mixture, as by fusion, of two or more metals. Herein, all reference to wt % of particles is meant to include the surface coating. Many suppliers of nanoparticles use undisclosed or proprietary surface coatings that act as dispersing aids. Herein, all reference to wt % of particles is meant to include the undisclosed or proprietary coatings that the manufacturer may have added as a dispersant aid. For instance, a commercial copper nanopowder is considered nominally 100 wt % copper.

Herein, by “O-, N-, S-, or Se-based functional groups” is meant univalent groups other than hydrocarbyl and substituted hydrocarbyl that comprise O-, N-, S-, or Se-heteroatoms, wherein the free valence is located on this heteroatom. Examples of O-, N-, S-, and Se-based functional groups include alkoxides, amidos, thiolates, and selenolates.

### Inks

One aspect of this invention is an ink comprising:
(a) a plurality of CIGS/Se microparticles;
(b) a plurality of particles selected from the group consisting of:
   CIGS/Se nanoparticles; elemental Cu-, In-, or Ga-containing particles; binary or ternary Cu-, In-, or Ga-containing chalcogenide particles; and mixtures thereof; and
(c) a vehicle.

This ink is referred to as a CIGS/Se precursor ink, as it contains the precursors for forming a CIGS/Se thin film. In some embodiments, the ink consists essentially of components (a)-(c).

Chalcogen Sources.

In some embodiments, the ink comprises the CIGS/Se nanoparticles. In some embodiments, the ink comprises Cu-, In-, or Ga-containing chalcogenide particles selected from the group consisting of: sulfide particles, selenide particles, sulfide/selenide particles, and mixtures thereof. In some embodiments, the ink further comprises an elemental chalcogen selected from the group consisting of: sulfur, selenium, and mixtures thereof.

Molar Ratios of the Ink.

In some embodiments, the molar ratio of Cu:(In+Ga) is about 1 in the ink. In some embodiments, the molar ratio of Cu:(In+Ga) is less than 1. In some embodiments, the molar ratio of total chalcogen to (Cu+In+Ga) is at least about 1 in the ink.

As defined herein, the moles of total chalcogen are determined by multiplying the moles of each chalcogen-containing species by the number of equivalents of chalcogen that it comprises and then summing these quantities. The moles of (Cu+In+Ga) are determined by multiplying the moles of each Cu-, In-, or Ga-containing species by the number of equivalents of Cu, In, or Ga that it comprises and then summing these quantities. As defined herein, sources for the total chalcogen include CIGS/Se microparticles and nanoparticles, chalcogenide particles and elemental chalcogen ink components. As an example, the molar ratio of total chalcogen to (Cu+In+Ga) for an ink comprising CuInS₂ microparticles, Cu₂S particles, In particles, and sulfur=[2(moles CuInS₂)+(moles of Cu₂S)+(moles of S)]/[2(moles CuInS₂)+2(moles of Cu₂S)+(moles of In)].

Particle Sizes.

The particles can be purchased or synthesized by known techniques such milling and sieving of bulk quantities of the material. In some embodiments, the particles have an average longest dimension of less than about 5 microns, 4 microns, 3 microns, 2 microns, 1.5 microns, 1.25 microns, 1.0 micron, or 0.75 micron.

Microparticles.

In some embodiments the particles comprise microparticles. The microparticles have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25, 50, 75, 100, 125, 150, 175, or 200 microns.

In embodiments in which in which the average longest dimension of the microparticles is less than the average thickness of the coated and/or annealed absorber layer, useful size ranges for microparticles are at least about 0.5 to about 10 microns, 0.6 to 5 microns, 0.6 to 3 microns, 0.6 to 2 microns, 0.6 to 1.5 microns, 0.6 to 1.2 microns, 0.8 to 2 microns, 1.0 to 3.0 microns, 1.0 to 2.0 microns, or 0.8 to 1.5 microns. In embodiments in which the average longest dimension of the microparticles is longer than the average thickness of the coated and/or annealed absorber layer, useful size ranges for microparticles are at least about 1 to about 200 microns, 2 to 200 microns, 2 to 100 microns, 3 to 100 microns, 2 to 50 microns, 2 to 25 microns, 2 to 20 microns, 2 to 15 microns, 2 to 10 microns, 2 to 5 microns, 4 to 50 microns, 4 to 25 microns, 4 to 20, 4 to 15, 4 to 10 microns, 6 to 50 microns, 6 to 25 microns, 6 to 20 microns, 6 to 15 microns, 6 to 10 microns, 10 to 50 microns, 10 to 25 microns, or 10 to 20 microns. The average thickness of the coated and/or annealed absorber layer can be determined by profilometry. The average longest dimension of the microparticles can be determined by electron microscopy.

Nanoparticles.

In some embodiments, the particles comprise nanoparticles. The nanoparticles can have an average longest dimension of less than about 500 nm, 400 nm, 300 nm, 250 nm, 200 nm, 150 nm, or 100 nm, as determined by electron microscopy. The nanoparticles can be purchased or synthesized by known techniques, such as: decomposition and reduction of metal salts and complexes; chemical vapor deposition; electrochemical deposition; use of gamma-, x-ray, laser or UV-irradiation; ultrasonic or microwave treatment; electron- or ion-beams; arc discharge; electric explosion of wires; or biosynthesis.

Capping Agent.

In some embodiments, the particles further comprise a capping agent. The capping agent can aid in the dispersion of particles and can also inhibit their interaction and agglomeration in the ink.

Suitable capping agents include:
(a) Organic molecules that contain functional groups such as N-, O-, S-, Se- or P-based functional groups;
(b) Lewis bases;
(c) Amines, thiols, selenols, phosphine oxides, phosphines, phosphinic acids, pyrrolidones, pyridines, carboxylates, phosphates, heteroaromatics, peptides, and alcohols;
(d) Alkyl amines, alkyl thiols, alkyl selenols, trialkylphosphine oxide, trialkylphosphines, alkylphosphonic acids, polyvinylpyrrolidone, polycarboxylates, polyphosphates, polyamines, pyridine, alkylpyridines, aminopyridines, peptides comprising cysteine and/or histidine residues, ethanolamines, citrates, thioglycolic acid, oleic acid, and polyethylene glycol;
(e) Inorganic chalcogenides, including metal chalcogenides, and zintl ions;
(f) S²⁻, Se²⁻, Se₂²⁻, Se₃²⁻, Se₄²⁻, Se₆²⁻, Te₂²⁻, Te₃²⁻, Te₄²⁻, In₂Se₄²⁻, and In₂Te₄²⁻, wherein the positively charged counterions can be alkali metal ions, ammonium, hydrazinium, or tetraalkylammonium;
(g) Degradable capping agents, including dichalcogenocarbamates, monochalcogenocarbamates, xanthates, trithiocarbonates, dichalcogenoimidodiphosphates, thiobiurets, dithiobiurets, chalcogenosemicarbazides, and tetrazoles. These capping agents can be degraded by thermal and/or chemical processes, such as acid- and base-catalyzed processes. Degradable capping agents include: dialkyl dithiocarbamates, dialkyl monothiocarbamates, dialkyl diselenocarbamates, dialkyl monoselenocarbamates, alkyl xanthates, alkyl trithiocarbonates, disulfidoimidodiphosphates, diselenoimidodiphosphates, tetraalkyl thiobiurets, tetraalkyl dithiobiurets, thiosemicarbazides, selenosemicarbazides, tetrazole, alkyl tetrazoles, amino-tetrazoles, thio-tetrazoles, and carboxylated tetrazoles. In some embodiments, Lewis bases (e.g., amines) can be added to nanoparticles stabilized by carbamate, xanthate, and trithiocarbonate capping agents to catalyze their removal from the nanoparticle;
(h) Molecular precursor complexes to copper chalcogenides, indium chalcogenides, and gallium chalcogenides. Ligands for these molecular precursor complexes include: thio groups, seleno groups, thiolates, selenolates, and thermally degradable ligands, as described above;
(i) Molecular precursor complexes to CuS/Se, Cu₂S/Se, InS/Se, In₂(S/Se)₃, GaS/Se, CuIn(S/Se)₂, and Cu(In/Ga)(S/Se)₂;
(j) The solvent in which the particle is formed, such as oleylamine; and
(k) Short-chain carboxylic acids, such as formic, acetic, or oxalic acids.

The Lewis base can be chosen such that it has a boiling temperature at ambient pressure that is greater than or equal to about 200° C., 150° C., 120° C., or 100° C., and/or can be selected from the group consisting of: organic amines, phosphine oxides, phosphines, thiols, and mixtures thereof. In some embodiments, the capping agent comprises a surfactant or a dispersant.

Volatile Capping Agents. In some embodiments, the particles comprise a volatile capping agent. A capping agent is considered volatile if, instead of decomposing and introducing impurities when a composition or ink of nanoparticles is formed into a film, it evaporates during film deposition, drying or annealing. Volatile capping agents include those having a boiling point less than about 200° C., 150° C., 120° C., or 100° C. at ambient pressure. Volatile capping agents may be adsorbed or bonded onto particles during synthesis or during an exchange reaction. Thus, in one embodiment, particles, or an ink or reaction mixture of particles stabilized by a first capping agent, as incorporated during synthesis, are mixed with a second capping agent that has greater volatility to exchange in the particles the second capping agent for the first capping agent. Suitable volatile capping agents include: ammonia, methyl amine, ethyl amine, propylamine, butylamine, tetramethylethylene diamine, acetonitrile, ethyl acetate, butanol, pyridine, ethanethiol, propanethiol, butanethiol, t-butylthiol, pentanethiol, hexanethiol, tetrahydrofuran, and diethyl ether. Suitable volatile capping agents can also include: amines, amidos, amides, nitriles, isonitriles, cyanates, isocyanates, thiocyanates, isothiocyanates, azides, thiocarbonyls, thiols, thiolates, sulfides, sulfinates, sulfonates, phosphates, phosphines, phosphites, hydroxyls, hydroxides, alcohols, alcoholates, phenols, phenolates, ethers, carbonyls, carboxylates, carboxylic acids, carboxylic acid anhydrides, glycidyls, and mixtures thereof.

### CIGS/Se Microparticles.

The ink comprises a plurality of CIGS/Se microparticles. The CIGS/Se microparticles can be synthesized by methods known in the art. A useful method for the synthesis of CISe microparticles involves reacting Cu—In alloy and Se molten fluxes. The crystal size of the materials can be controlled by the temperature and duration of the recrystallization process and by the chemical nature of the flux. A particularly useful aqueous method for synthesizing CIGS/Se particles comprises:
(a) providing a first aqueous solution comprising two or more metal salts and one or more ligands;
(b) optionally, adding a pH-modifying substance to form a second aqueous solution;
(c) combining the first or second aqueous solution with a chalcogen source to provide a reaction mixture; and
(d) agitating and optionally heating the reaction mixture to produce metal chalcogenide nanoparticles.
(e) separating the metal chalcogenide nanoparticles from reaction by-products; and
(f) heating the metal chalcogenide nanoparticles to provide crystalline multinary-metal chalcogenide particles.

The annealing time can be used to control the CIGS/Se particle size, with particles ranging from nanoparticles to microparticles, as annealing time lengthens. In some instances, the microparticles synthesized via these methods may be larger than desired. In such cases, the CIGS/Se microparticles can be milled or sieved using standard techniques to achieve the desired particle size.

In some instances, the CIGS/Se microparticles comprise a capping agent. The coated CIGS/Se microparticles can be synthesized by standard techniques known in the art, such as mixing the microparticle with a liquid capping agent, optionally with heating, and then washing the coated particles to remove excess capping agent. CIGS/Se microparticles capped with CIGS/Se molecular precursors can be synthesized by mixing CIGS/Se microparticles with a CIGS/Se molecular precursor ink comprising:
(i) a copper source selected from the group consisting of copper complexes of nitrogen-, oxygen-, carbon-, sulfur-, or selenium-based organic ligands, copper sulfides, copper selenides, and mixtures thereof;
(ii) an indium source selected from the group consisting of indium complexes of nitrogen-, oxygen-, carbon-, sulfur-, or selenium-based organic ligands, indium sulfides, indium selenides, and mixtures thereof;
(iii) optionally, a gallium source selected from the group consisting of gallium complexes of nitrogen-, oxygen-, carbon-, sulfur-, or selenium-based organic ligands, gallium sulfides, gallium selenides, and mixtures thereof; and
(iv) a vehicle, comprising a liquid chalcogen compound, a solvent, or a mixture thereof.

Suitable chalcogen compounds include: elemental S, elemental Se, CS₂, CSe₂, CSSe, R¹S—Z, R¹Se—Z, R¹S—SR¹, R¹Se—SeR¹, R²C(S)S—Z, R²C(Se)Se—Z, R²C(Se)S—Z, R¹C(O)S—Z, R¹C(O)Se—Z, and mixtures thereof, wherein each Z is independently selected from the group consisting of: H, NR⁴₄, and SiR⁵₃; wherein each R¹ and R⁵ is independently selected from the group consisting of: hydrocarbyl and O-, N-, S-, Se-, halogen- or tri(hydrocarbyl)silyl-substituted hydrocarbyl; each R² is independently selected from the group consisting of hydrocarbyl, O-, N-, S-, Se-, halogen-, or tri(hydrocarbyl)silyl-substituted hydrocarbyl, and O-, N-, S-, or Se-based functional groups; and each R⁴ is independently selected from the group consisting of hydrogen, O-, N-, S-, Se-, halogen- or tri(hydrocarbyl)silyl-substituted hydrocarbyl, and O-, N-, S-, or Se-based functional groups. In some embodiments, elemental sulfur, elemental selenium, or a mixture of elemental sulfur and selenium is present.

In some embodiments, the mixture is heat-processed at a temperature of greater than about 50° C., 75° C., 90° C., 100° C., 110° C., 120° C., 130° C., 140° C., 150° C., 160° C., 170° C., 180° C. or 190° C. Suitable heating methods include conventional heating and micowave heating. In some embodiments, the CIGS/Se microparticles are mixed with a molecular precursor ink wherein solvent(s) comprise(s) less than about 90 wt %, 80 wt %, 70 wt %, 60 wt %, or 50 wt % of the ink, based upon the total weight of the ink. Following mixing and optional heating, the CIGS/Se microparticles are washed with solvent to remove excess molecular precursor.

### Plurality of Particles.

Molar Ratios of the Plurality of Particles.

In some embodiments, the molar ratio of Cu:(In+Ga) is about 1 in the plurality of particles. In some embodiments, the molar ratio of Cu:(In+Ga) is less than 1. In some embodiments, the molar ratio of total chalcogen to (Cu+In+Ga) is at least about 1 in the plurality of particles. As defined herein, the moles of total chalcogen and the moles of (Cu+In+Ga) are determined as defined above for the ink.

CIGS/Se Nanoparticles.

In some embodiments, the plurality of particles comprises CIGS/Se nanoparticles. In some embodiments, the plurality of particles consists essentially of CIGS/Se nanoparticles. The CIGS/Se nanoparticles can be synthesized by methods known in the art, as described above. CIGSe nanoparticles are available commercially from American Elements (Los Angeles, Calif.). A particularly useful method for synthesizing CIGS/Se nanoparticles is the aqueous method for synthesizing CIGS/Se particles described above. In some instances, the CIGS/Se nanoparticles comprises a capping agent. Capped CIGS and CIS nanoparticles are commercially available from Nanoco (Manchester, UK).

Elemental Particles.

In some embodiments, the plurality of particles comprises elemental Cu-, In, or Ga-containing particles. In some embodiments, the plurality of particles consists essentially of elemental Cu-, In- or Ga-containing particles or mixtures thereof. In some embodiments, the plurality of particles consists essentially of elemental Cu- or In-containing particles or mixtures thereof. Suitable elemental Cu-, In-, or Ga-containing particles include: Cu particles, Cu—In alloy particles, Cu—Ga alloy particles, Cu—In—Ga alloy particles, In particles, In—Ga alloy particles, Ga particles; and mixtures thereof. In some embodiments, the elemental Cu-, In-, or Ga-containing particles are nanoparticles. The elemental Cu- or In-containing nanoparticles can be obtained from Sigma-Aldrich (St. Louis, Mo.), Nanostructured and Amorphous Materials, Inc. (Houston, Tex.), American Elements (Los Angeles, Calif.), Inframat Advanced Materials LLC (Manchester, Conn.), Xuzhou Jiechuang New Material Technology Co., Ltd. (Guangdong, China), Absolute Co. Ltd. (Volgograd, Russian Federation), MTI Corporation (Richmond, Va.), or Reade Advanced Materials (Providence, R.I.). Elemental Cu-, In-, or Ga-containing nanoparticles can also be synthesized according to known techniques, as described above. In some instances, the elemental Cu-, In-, or Ga-containing particles comprise a capping agent.

Binary or Ternary Chalcogenide Particles.

In some embodiments, the plurality of particles comprises binary or ternary Cu-, In-, or Ga-containing chalcogenide particles. In some embodiments, the plurality of particles consists essentially of binary or ternary Cu-, In-, or Ga-containing chalcogenide particles or mixtures thereof. In some embodiments, the plurality of particles consists essentially of elemental Cu-, In- or Ga-containing particles and binary or ternary Cu-, In-, or Ga-containing chalcogenide particles. In some embodiments, the plurality of particles consists essentially of binary or ternary Cu- or In-containing chalcogenide particles or mixtures thereof. In some embodiments, the chalcogenide is a sulfide or selenide. Suitable Cu-, In-, or Ga-containing binary or ternary chalcogenide particles include: Cu₂S/Se particles, CuS/Se particles, In₂(S,Se)₃ particles, InS/Se particles, Ga₂(S,Se)₃ particles, GaS/Se particles, (Ga,In)₂(S,Se)₃ particles, and mixtures thereof. A particularly useful method for synthesizing mixtures of copper-, indium- and, optionally, gallium-containing chalcogenide nanoparticles comprises steps (a)-(d) of the above aqueous method for synthesizing CIGS/Se particles. In some instances, the binary or ternary Cu-, In-, or Ga-containing chalcogenide particles comprise a capping agent.

Capped Nanoparticles.

In some instances, the CIGS/Se nanoparticles comprise a capping agent. Capped CIGS and CIS nanoparticles are commercially available from Nanoco (Manchester, UK).

Coated binary, ternary, and quaternary chalcogenide nanoparticles, including CuS, CuSe, In₂S₃, In₂Se₃, Ga₂S₃, Ga₂Se₃, CuInS₂, CuInSe₂, CuGaS₂, CuGaSe₂, Cu(In,Ga)S₂ and Cu(In,Ga)Se₂ can be prepared from corresponding metal salts or complexes by reaction of the metal salt or complex with a source of sulfide or selenide in the presence of one or more stabilizing agents at a temperature between 0° C. and 500° C., or between 150° C. and 350° C. In some circumstances, the stabilizing agent also provides the coating. The chalcogenide nanoparticles can be isolated, for example, by precipitation by a non-solvent followed by centrifugation, and can be further purified by washing, or dissolving and re-precipitating. Suitable metal salts and complexes for this synthetic route include Cu(I), Cu(II), In(III), and Ga(III) halides, acetates, nitrates, and 2,4-pentanedionates. Suitable chalcogen sources include elemental sulfur, elemental selenium, Na₂S, Na₂Se, (NH₄)₂S, (NH₄)₂Se, thiourea, and thioacetamide. Suitable stabilizing agents include the capping agents disclosed above. In particular, suitable stabilizing agents include: dodecylamine, tetradecyl amine, hexadecyl amine, octadecyl amine, oleylamine, trioctyl amine, trioctylphosphine oxide, other trialkylphosphine oxides, and trialkylphosphines.

Cu₂S nanoparticles can be synthesized by a solvothermal process, in which the metal salt is dissolved in deionized water. A long-chain alkyl thiol or selenol (e.g., 1-dodecanethiol or 1-dodecaneselenol) can serve as both the chalcogen source and as a dispersant for nanoparticles. Some additional ligands, including acetate and chloride, can be added in the form of an acid or a salt. The reaction is typically conducted at a temperature between 150° C. and 300° C. and at a pressure between 150 psig to 250 psig nitrogen. After cooling, the product can be isolated from the non-aqueous phase, for example, by precipitation using a non-solvent and filtration.

The chalcogenide nanoparticles can also be synthesized by an alternative solvothermal process in which the corresponding metal salt is dispersed along with thioacetamide, thiourea, selenoacetamide, selenourea or other source of sulfide or selenide ions and an organic stabilizing agent (e.g., a long-chain alkyl thiol or a long-chain alkyl amine) in a suitable solvent at a temperature between 150° C. and 300° C. The reaction is typically conducted at a pressure between 150 psig nitrogen and 250 psig nitrogen. Suitable metal salts for this synthetic route include Cu(I), Cu(II), In(III), and Ga(III) halides, acetates, nitrates, and 2,4-pentaned ionates.

The resultant chalcogenide nanoparticles obtained from any of the three routes are coated with the organic stabilizing agent(s), as can be determined by secondary ion mass spectrometry and nuclear magnetic resonance spectroscopy. The structure of the inorganic crystalline core of the coated nanoparticles can be determined by X-ray diffraction (XRD) and transmission electron microscopy (TEM) techniques.

Vehicle. The ink comprises a vehicle to carry the particles. The vehicle is typically a fluid or a low-melting solid with a melting point of less than about 100° C., 90° C., 80° C., 70° C., 60° C., 50° C., 40° C., or 30° C. In some embodiments, the vehicle comprises one or more solvents. Suitable solvents include: aromatics, heteroaromatics, alkanes, chlorinated alkanes, ketones, esters, nitriles, amides, amines, thiols, selenols, pyrrolidinones, ethers, thioethers, selenoethers, alcohols, water, and mixtures thereof. Useful examples of these solvents include toluene, p-xylene, mesitylene, benzene, chlorobenzene, dichlorobenzene, trichlorobenzene, pyridine, 2-aminopyridine, 3-aminopyridine, 2,2,4-trimethylpentane, n-octane, n-hexane, n-heptane, n-pentane, cyclohexane, chloroform, dichloromethane, 1,1,1-trichloroethane, 1,1,2-trichloroethane, 1,1,2,2-tetrachloroethane, 2-butanone, acetone, acetophenone, ethyl acetate, acetonitrile, benzonitrile, N,N-dimethylformamide, butylamine, hexylamine, octylamine, 3-methoxypropylamine, 2-methylbutylamine, isoamylamine, 1-propanethiol, 1-butanethiol, 2-butanethiol, 2-methyl-1-propanethiol, t-butyl thiol, 1-pentanethiol, 3-methyl-1-butanethiol, cyclopentanethiol, 1-hexanethiol, cyclohexanethiol, 1-heptanethiol, 1-octanethiol, 2-ethyhexanethiol, 1-nonanethiol, tert-nonyl mercaptan, 1-decanethiol, mercaptoethanol, 4-cyano-1-butanethiol, butyl 3-mercaptoproprionate, methyl 3-mercaptoproprionate, 1-mercapto-2-propanol, 3-mercapto-1-propanol, 4-mercapto-1-butanol, 6-mercapto-1-hexanol, 2-phenylethanethiol, thiophenol, N-methyl-2-pyrrolidinone, tetrahydrofuran, 2,5-dimethylfuran, diethyl ether, ethylene glycol diethyl ether, diethylsulfide, diethylselenide, 2-methoxyethanol, isopropanol, butanol, ethanol, methanol and mixtures thereof.

In some embodiments, the wt % of the vehicle in the ink is about 95 to about 5 wt %, 95 to 50 wt %, 95 to 60 wt %, 95 to 70 wt %, 95 to 80 wt %, 90 to 10 wt %, 80 to 20 wt %, 70 to 30 wt %, 60 to 40 wt %, 98 to 50 wt %, 98 to 60 wt %, 98 to 70 wt %, 98 to 75 wt %, 98 to 80 wt %, 98 to 85 wt %, 95 to 75 wt %, 95 to 80 wt %, or 95 to 85 wt % based upon the total weight of the ink. In some embodiments, the vehicle may function as a dispersant or capping agent, as well as being the carrier vehicle for the particles. Solvent-based vehicles that are particularly useful as capping agents comprise heteroaromatics, amines, thiols, selenols, thioethers, or selenoethers.

### Additional Ink Components

In various embodiments the ink further comprises additive(s), an elemental chalcogen, or mixtures thereof.

Additives.

In some embodiments, the ink further comprises one or more additives. Suitable additives include dispersants, surfactants, polymers, binders, ligands, capping agents, defoamers, thickening agents, corrosion inhibitors, plasticizers, thixotropic agents, viscosity modifiers, and dopants. In some embodiments, additives are selected from the group consisting of: capping agents, dopants, polymers, and surfactants. In some embodiments, the ink comprises up to about 10 wt %, 7.5 wt %, 5 wt %, 2.5 wt % or 1 wt % additives, based upon the total weight of the ink. Suitable capping agents comprise the capping agents, including volatile capping agents, described above.

Dopants.

Suitable dopants include sodium and alkali-containing compounds. In some embodiments, the alkali-containing compounds are selected from the group consisting of: alkali compounds comprising N-, O-, C-, S-, or Se-based organic ligands, alkali sulfides, alkali selenides, and mixtures thereof. In other embodiments, the dopant comprises an alkali-containing compound selected from the group consisting of: alkali-compounds comprising amidos; alkoxides; acetylacetonates; carboxylates; hydrocarbyls; O-, N-, S-, Se-, halogen-, or tri(hydrocarbyl)silyl-substituted hydrocarbyls; thiolates and selenolates; thio-, seleno-, and dithiocarboxylates; dithio-, diseleno-, and thioselenocarbamates; and dithioxanthogenates. Other suitable dopants include antimony chalcogenides selected from the group consisting of antimony sulfide and antimony selenide.

Polymers and Surfactants.

Suitable polymeric additives include vinylpyrrolidone-vinylacetate copolymers and (meth)acrylate copolymers, including PVP/VA E-535 (International Specialty Products), and Elvacite® 2028 binder and Elvacite® 2008 binder (Lucite International, Inc.). In some embodiments, polymers can function as binders or dispersants.

Suitable surfactants comprise siloxy-, fluoryl-, alkyl-, alkynyl-, and ammonium-substituted surfactants. These include, for example, Byk® surfactants (Byk Chemie), Zonyl® surfactants (DuPont), Triton® surfactants (Dow), Surfynol® surfactants (Air Products), Dynol® surfactants (Air Products), and Tego® surfactants (Evonik Industries AG). In certain embodiments, surfactants function as coating aids, capping agents, or dispersants.

In some embodiments, the ink comprises one or more binders or surfactants selected from the group consisting of: decomposable binders; decomposable surfactants; cleavable surfactants; surfactants with a boiling point less than about 250° C.; and mixtures thereof. Suitable decomposable binders include: homo- and co-polymers of polyethers; homo- and co-polymers of polylactides; homo- and co-polymers of polycarbonates including, for example, Novomer PPC (Novomer, Inc.); homo- and co-polymers of poly[3-hydroxybutyric acid]; homo- and co-polymers of polymethacrylates; and mixtures thereof. A suitable low-boiling surfactant is Surfynol® 61 surfactant from Air Products. Cleavable surfactants useful herein as capping agents include Diels-Alder adducts, thiirane oxides, sulfones, acetals, ketals, carbonates, and ortho esters. Suitable cleavable surfactants include: alkyl-substituted Diels Alder adducts, Diels Alder adducts of furans; thiirane oxide; alkyl thiirane oxides; aryl thiirane oxides; piperylene sulfone, butadiene sulfone, isoprene sulfone, 2,5-dihydro-3-thiophene carboxylic acid-1,1-dioxide-alkyl esters, alkyl acetals, alkyl ketals, alkyl 1,3-dioxolanes, alkyl 1,3-dioxanes, hydroxyl acetals, alkyl glucosides, ether acetals, polyoxyethylene acetals, alkyl carbonates, ether carbonates, polyoxyethylene carbonates, ortho esters of formates, alkyl ortho esters, ether ortho esters, and polyoxyethylene ortho esters.

Elemental Chalcogen.

In some embodiments, the ink comprises an elemental chalcogen selected from the group consisting of sulfur, selenium, and mixtures thereof. Useful forms of sulfur and selenium include powders that can be obtained from Sigma-Aldrich (St. Louis, Mo.) and Alfa Aesar (Ward Hill, Mass.). In some embodiments, the chalcogen powder is soluble in the ink vehicle. If the chalcogen is not soluble in the vehicle, its particle size can be 1 nm to 200 microns. In some embodiments, the particles have an average longest dimension of less than about 100 microns, 50 microns, 25 microns, 10 microns, 5 microns, 4 microns, 3 microns, 2 microns, 1.5 microns, 1.25 microns, 1.0 micron, 0.75 micron, 0.5 micron, 0.25 micron, or 0.1 micron. Preferably, the chalcogen particles are smaller than the thickness of the film that is to be formed. The chalcogen particles can be formed by ball milling, evaporation-condensation, melting and spraying (“atomization”) to form droplets, or emulsification to form colloids.

Ink Preparation.

Preparing the ink typically comprises mixing the components by any conventional method. In some embodiments, the preparation is conducted under an inert atmosphere. In some embodiments, the wt % of the CIGS/Se microparticles, based upon the total weight of the microparticles and plurality of particles, ranges from about 95 to about 5 wt %. In some embodiments, the wt % of the microparticles, based upon the weight of the microparticles and the plurality of particles, is less than about 90 wt %, 80 wt %, 70 wt %, 60 wt %, 50 wt %, 40 wt %, 30 wt %, 20 wt %, 10 wt %, or 5 wt %.

In some embodiments, particularly those in which the average longest dimension of the microparticles is longer than the desired average thickness of the coated and/or annealed layer, the ink is prepared on a substrate. Suitable substrates for this purpose are as described below. For example, the plurality of particles can be deposited on the substrate, with suitable deposition techniques as described below. Then the CIGS/Se microparticles can be added to the plurality of particles by techniques such as sprinkling the microparticles onto the deposited plurality of particles.

Heat-Processing of the Ink.

In some embodiments, the vehicle and at least one of a) the plurality of CIGS/Se microparticles and b) the plurality of particles are heat-processed at a temperature of greater than about 90° C., 100° C., 110° C., 120° C., 130° C., 140° C., 150° C., 160° C., 170° C., 180° C., or 190° C. before coating on the substrate. Suitable heating methods include conventional heating and microwave heating. In some embodiments, it has been found that this heat-processing step aids the dispersion of the plurality of CIGS/Se microparticles and/or the plurality of particles within the vehicle. Films made from heat-processed inks typically have smooth surfaces, an even distribution of particles within the film as observed by SEM, and improved performance in photovoltaic devices as compared to inks of the same composition that are not heat-processed. This optional heat-processing step is typically carried out under an inert atmosphere. The ink produced at this stage can be stored for months without any noticeable decrease in efficacy.

Mixtures of Inks.

In some embodiments two or more inks are prepared separately, with each ink comprising CIGS/Se microparticles and a plurality of particles. The two or more inks can then be combined following mixing or following heat-processing. This method is especially useful for controlling stoichiometry and obtaining CIGS/Se of high purity, as prior to mixing, separate films from each ink can be coated, annealed, and analyzed by XRD. The XRD results can then guide the selection of the type and amount of each ink to be combined. For example, an ink yielding an annealed film of CIGS/Se with traces of copper sulfide can be combined with an ink yielding an annealed film of CIGS/Se with traces of indium sulfide, to form an ink that yields an annealed film comprising only CIGS/Se, as determined by XRD. In other embodiments, an ink comprising a complete set of reagents is combined with ink(s) comprising a partial set of reagents. As an example, an ink containing only an indium source can be added in varying amounts to an ink comprising a complete set of reagents, and the stoichiometry can be optimized based upon the resulting device performances of annealed films of the mixtures.

### Coated Substrate

Another aspect of this invention is a process comprising disposing an ink onto a substrate to form a coated substrate, wherein the ink comprises:
(a) a plurality of CIGS/Se microparticles;
(b) a plurality of particles selected from the group consisting of:
   CIGS/Se nanoparticles; elemental Cu-, In-, or Ga-containing particles; binary or ternary Cu-, In-, or Ga-containing chalcogenide particles; and mixtures thereof; and
(c) a vehicle.

Another aspect of this invention is a coated substrate comprising:
(a) a substrate; and
(b) at least one layer disposed on the substrate comprising:
   (i) a plurality of CIGS/Se microparticles; and
   (ii) a plurality of particles selected from the group consisting of:
      CIGS/Se nanoparticles; elemental Cu-, In-, or Ga-containing particles; binary or ternary Cu-, In-, or Ga-containing chalcogenide particles; and mixtures thereof.

In some embodiments, the at least one layer consists essentially of components (i)-(ii). Embodiments and descriptions for the plurality of CIGS/Se particles and the plurality of particles are the same as described above for the ink. In various embodiments, the at least one layer further comprises a vehicle, including one or more solvents; one or more additive(s); an elemental chalcogen; or mixtures thereof. In various embodiments of the at least one layer of the coated substrate, at least one of (i) the plurality of CIGS/Se microparticles and (ii) the plurality of particles have been heat-processed at a temperature above about 90° C.

Substrate.

The substrate onto which the ink is disposed can be rigid or flexible. In one embodiment, the substrate comprises: (i) a base; and (ii) optionally, an electrically conductive coating on the base. The base material is selected from the group consisting of glass, metals, ceramics, and polymeric films. Suitable base materials include metal foils, plastics, polymers, metalized plastics, glass, solar glass, low-iron glass, green glass, soda-lime glass, metalized glass, steel, stainless steel, aluminum, ceramics, metal plates, metalized ceramic plates, and metalized polymer plates. In some embodiments, the base material comprises a filled polymer (e.g., a polyimide and an inorganic filler). In some embodiments, the base material comprises a metal (e.g., stainless steel) coated with a thin insulating layer (e.g., alumina).

Suitable electrically conductive coatings include metal conductors, transparent conducting oxides, and organic conductors. Of particular interest are substrates of molybdenum-coated soda-lime glass, molybdenum-coated polyimide films, and molybdenum-coated polyimide films further comprising a thin layer of a sodium compound (e.g., NaF, Na₂S, or Na₂Se).

Ink Deposition.

The ink is disposed on a substrate to provide a coated substrate by solution-based coating or printing techniques, including spin-coating, spray-coating, dip-coating, rod-coating, drop-cast coating, roller-coating, slot-die coating, draw-down coating, ink-jet printing, contact printing, gravure printing, flexographic printing, and screen printing. The coating can be dried by evaporation, by applying vacuum, by heating, by blowing, or by combinations thereof. In some embodiments, the substrate and disposed ink are heated at a temperature from 80-350° C., 100-300° C., 120-250° C., 150-190° C., or 120-170° C. to remove at least a portion of the solvent and any by-products, such as volatile capping agents. The drying step can be a separate, distinct step, or can occur as the substrate and precursor ink are heated in an annealing step.

Coated Substrate.

In some embodiments, the coated substrate comprises at least one layer, wherein the at least one layer is derived from the ink. In some embodiments, the molar ratio of Cu:(In+Ga) in the at least one layer is about 1. In some embodiments, the molar ratio of Cu:(In+Ga) in the at least one layer is less than 1. In some embodiments of the at least one layer, the plurality of particles comprises CIGS/Se nanoparticles or binary or ternary Cu-, In-, or Ga-containing chalcogenide particles, or the at least one layer further comprises an elemental chalcogen. In some embodiments, the chalcogenide particles are selected from the group consisting of: sulfide particles, selenide particles, sulfide/selenide particles, and mixtures thereof; and the elemental chalcogen is sulfur, selenium, or a mixture thereof. In some embodiments, the molar ratio of total chalcogen to (Cu+In+Ga) in the at least one layer is at least about 1 and is determined as described above for the ink.

In some embodiments, the at least one layer of the coated substrate comprises or consists essentially of CIGS/Se microparticles and CIGS/Se nanoparticles. In some embodiments, the at least one layer comprises or consists essentially of CIGS/Se microparticles and elemental Cu-, In-, or Ga-containing particles. In some embodiments, the at least one layer comprises or consists essentially of CIGS/Se microparticles and binary or ternary Cu-, In-, or Ga-containing chalcogenide particles. In some embodiments, the at least one layer comprises or consists essentially of CIGS/Se microparticles; elemental Cu-, In-, or Ga-containing particles; and binary or ternary Cu-, In-, or Ga-containing chalcogenide particles.

The particle sizes may be determined by techniques such as electron microscopy. In some embodiments, the CIGS/Se microparticles of the coated substrate have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25 or 50 microns, and the plurality of particles of the coated substrate has an average longest dimension of less than about 10, 7.5, 5.0, 4.0, 3.0, 2.0, 1.5, 1.0, 0.75, 0.5, 0.4, 0.3, 0.2, or 0.1 microns. In some embodiments, the plurality of particles comprises or consists essentially of nanoparticles.

In some embodiments, the absolute value of the difference between the average longest dimension of the CIGS/Se microparticles of the coated substrate and the average thickness of the at least one layer is at least about 0.1, 0.2, 0.3, 0.4, 0.5, 0.75, 1.0, 1.5, 2.0, 2.5, 3.0, 5.0, 10.0, 15.0, 20.0 or 25.0 microns. In some embodiments, the average longest dimension of the CIGS/Se microparticles of the coated substrate is less than the average thickness of the at least one layer.

As measured by profilometry, Ra (average roughness) is the arithmetic average deviation of roughness from the mean line within the assessment length. In some embodiments, the average longest dimension of the CIGS/Se microparticles of the coated substrate is less than the thickness of the at least one layer, and the plurality of particles of the coated substrate are nanoparticles having an average longest dimension of less than about 500 nm, 400 nm, 300 nm, 250 nm, 200 nm, 150 nm, or 100 nm, as determined by electron microscopy. In some embodiments, the average longest dimension of the CIGS/Se microparticles of the coated substrate is less than the thickness of the at least one layer, the plurality of particles of the coated substrate are nanoparticles, and the Ra of the at least one layer is less than about 1 micron, 0.9 micron, 0.8 micron, 0.7 micron, 0.6 micron, 0.5 micron, 0.4 micron or 0.3 micron, as measured by profilometry. In some embodiments, the average longest dimension of the CIGS/Se microparticles of the coated substrate is greater than the average thickness of the at least one layer.

Annealing.

In some embodiments, the coated substrate is heated at about 100-800° C., 200-800° C., 250-800° C., 300-800° C., 350-800° C., 400-650° C., 450-600° C., 450-550° C., 450-525° C., or 100-700° C. In some embodiments, the coated substrate is heated for a time in the range of about 1 min to about 48 h; 1 min to about 30 min; 10 min to about 10 h; 15 min to about 5 h; 20 min to about 3 h; or, 30 min to about 2 h. Typically, the annealing comprises thermal processing, rapid thermal processing (RTP), rapid thermal annealing (RTA), pulsed thermal processing (PTP), laser beam exposure, heating via IR lamps, electron beam exposure, pulsed electron beam processing, heating via microwave irradiation, or combinations thereof. Herein, RTP refers to a technology that can be used in place of standard furnaces and involves single-wafer processing, and fast heating and cooling rates. RTA is a subset of RTP, and consists of unique heat treatments for different effects, including activation of dopants, changing substrate interfaces, densifying and changing states of films, repairing damage, and moving dopants. Rapid thermal anneals are performed using either lamp-based heating, a hot chuck, or a hot plate. PTP involves thermally annealing structures at extremely high power densities for periods of very short duration, resulting, for example, in defect reduction. Similarly, pulsed electron beam processing uses a pulsed high-energy electron beam with short pulse duration. Pulsed processing is useful for processing thin films on temperature-sensitive substrates. The duration of the pulse is so short that little energy is transferred to the substrate, leaving it undamaged. In some embodiments, the annealing is carried out under an atmosphere comprising: an inert gas (nitrogen or a Group VIIIA gas, particularly argon); optionally hydrogen; and optionally, a chalcogen source such as selenium vapor, sulfur vapor, hydrogen sulfide, hydrogen selenide, diethyl selenide, or mixtures thereof. The annealing step can be carried out under an atmosphere comprising an inert gas, provided that the molar ratio of total chalcogen (Cu+In+Ga) in the coating is greater than about 1. If the molar ratio of total chalcogen to (Cu+In+Ga) is less than about 1, the annealing step is carried out in an atmosphere comprising an inert gas and a chalcogen source. In some embodiments, at least a portion of the chalcogen present in the coating (e.g., S) can be exchanged (e.g., S can be replaced by Se) by conducting the annealing step in the presence of a different chalcogen (e.g., Se). In some embodiments, annealings are conducted under a combination of atmospheres. For example, a first annealing is carried out under an inert atmosphere and a second annealing is carried out in an atmosphere comprising an inert gas and a chalcogen source as described above, or vice versa. In some embodiments, the annealing is conducted with slow heating and/or cooling steps, e.g., temperature ramps and/or declines of less than about 15° C./min, 10° C./min, 5° C./min, 2° C./min, or 1° C./min. In other embodiments, the annealing is conducted with rapid heating and/or cooling steps, e.g., temperature ramps and/or declines of greater than about 15° C. per min, 20° C. per min, 30° C. per min, 45° C. per min, or 60° C. per min.

Additional Layers.

In some embodiments, the coated substrate further comprises one or more additional layers. These one or more layers can be of the same composition as the at least one layer or can differ in composition. In some embodiments, particularly suitable additional layers comprise CIGS/Se precursors selected from the group consisting of: CIGS/Se molecular precursors, CIGS/Se nanoparticles, elemental Cu-, In- or Ga-containing nanoparticles; binary or ternary Cu-, In- or Ga-containing chalcogenide nanoparticles; and mixtures thereof. In some embodiments, the one or more additional layers are coated on top of the at least one layer. The top-coated additional layers can serve to planarize the surface of the at least one layer or fill in voids in the at least one layer. In some embodiments, the one or more additional layers are coated prior to coating the at least one layer. The one or more additional layers serve as underlayers that can improve the adhesion of the at least one layer and prevent any shorts that might result from voids in the at least one layer. In some embodiments, the additional layers are coated both prior to and subsequent to the coating of the at least one layer.

In some embodiments, a soft-bake step and/or annealing step occurs between coating the at least one layer and the one or more additional layers.

### Films.

Another aspect of this invention is a film comprising:
(a) an inorganic matrix; and
(b) CIGS/Se microparticles characterized by an average longest dimension of 0.5-200 microns, wherein the microparticles are embedded in the inorganic matrix.

CIGS/Se Composition. An annealed film comprising CIGS/Se is produced by the above annealing processes. In some embodiments, the coherent domain size of the CIGS/Se film is greater than about 30 nm, 40 nm, 50 nm, 60 nm, 70 nm, 80 nm, 90 nm, or 100 nm, as determined by XRD. In some embodiments, the molar ratio of Cu:(In+Ga) in the film is about 1. In some embodiments, the molar ratio of Cu:(In+Ga) in the film is less than 1.

In some embodiments, the annealed film comprises CIGS/Se microparticles embedded in an inorganic matrix. In some embodiments, the inorganic matrix comprises or consists essentially of CIGS/Se or CIGS/Se particles.

The composition and planar grain sizes of the annealed film, as determined by electron microscopy and EDX measurements, can vary depending on the ink composition, processing, and annealing conditions. According to these methods, in some embodiments, the microparticles are indistiguishable from the grains of the inorganic matrix in terms of size and/or composition, and in other embodiments, the microparticles are distinguishable from the grains of the inorganic matrix in terms of size and/or composition. In some embodiments, the planar grain size of the matrix is at least about 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 2.5, 3.0, 3.5, 4.0, 4.5, 5.0, 7.5, 10, 15, 20, 25 or 50 microns. In some embodiments, the CIGS/Se microparticles have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 3.5, 4.0, 5.0, 7.5, 10, 15, 20, 25 or 50 microns. In some embodiments, the absolute value of the difference between the average longest dimension of the CIGS/Se microparticles and the planar grain size of the inorganic matrix is at least about 0.1, 0.2, 0.3, 0.4, 0.5, 0.75, 1.0, 1.5, 2.0, 2.5, 3.0, 5.0, 7.5, 10.0, 15.0, 20.0 or 25.0 microns. In various embodiments, the average longest dimension of the microparticles is less than, greater than, or equivalent to the planar grain size of the inorganic matrix.

In various embodiments in which both the CIGS/Se microparticles and the inorganic matrix consist essentially of CIGS/Se, there can be differences in the composition of the CIGS/Se microparticles and the inorganic matrix. The differences can be due to differences in one or more of: (a) the fraction of chalcogenide present as sulfur or selenium in the CIGS/Se, (b) the molar ratio of Cu to In or of Cu to (In+Ga); (c) the molar ratio of In to Ga; (d) the molar ratio of total chalcogen to (Cu+In) or of total chalcogen to (Cu+In+Ga); (e) the amount and type of dopants; and (f) the amount and type of trace impurities.

In some embodiments, the composition of the matrix is given by Cu(InᵣGa₁₋ᵣ)(SₘSe₂₋ₘ) where 0≦m≦2 and 0<r≦1, and the composition of the microparticles is given by Cu(InₛGa₁₋ₛ)(SₙSe₂₋ₙ) where 0≦n≦2 and 0<s≦1, and the absolute value of the difference between m and n is at least about 0.1, 0.2, 0.3, 0.4, 0.5, 0.75, 1.0, 1.25, 1.5, 1.75, or 2.0; or the absolute value of the difference between r and s is at least about 0.05, 0.1, 0.2, 0.3, 0.4, 0.5, 0.75 or 1.0. In some embodiments, the molar ratio of Cu to (In+Ga) of the CIGS/Se microparticles is MR1 and the molar ratio of Cu to (In+Ga) of the CIGS/Se matrix is MR2, and the absolute value of the difference between MR1 and MR2 is at least about 0.1, 0.2, 0.3, 0.4, or 0.5. In some embodiments, the molar ratio of In to Ga of the CIGS/Se microparticles is MR3 and the molar ratio of In to Ga of the CIGS/Se matrix is MR4, and the difference between MR3 and MR4 is at least about 0.1, 0.2, 0.3, 0.4, or 0.5. In some embodiments, the molar ratio of total chalcogen to (Cu+In+Ga) of the CIGS/Se microparticles is MR5 and the molar ratio of total chalcogen to (Cu+In+Ga) of the CIGS/Se matrix is MR6, and the absolute value of the difference between MR5 and MR6 is at least about 0.1, 0.2, 0.3, 0.4, or 0.5. In some embodiments, a dopant is present in the film, and the absolute value of the difference between the wt % of the dopant in the CIGS/Se microparticles and in the inorganic matrix is at least about 0.05, 0.1, 0.2, 0.3, 0.4, 0.5, 0.75, or 1 wt %. In some embodiments, dopants comprise an alkali metal (e.g., Na) or Sb. In some embodiments, a trace impurity is present in the film, and the absolute value of the difference between the wt % of the impurity in the CIGS/Se microparticles and in the inorganic matrix is at least about 0.05, 0.1, 0.2, 0.3, 0.4, 0.5, 0.75, or 1 wt %. In some embodiments, trace impurities comprise one or more of F, Cl, Br, I, C, O, Ca, Al, W, Fe, Cr, and N.

In some embodiments, the absolute value of the difference between the average longest dimension of the CIGS/Se microparticles and the thickness of the annealed film is at least about 0.1, 0.2, 0.3, 0.4, 0.5, 0.75, 1.0, 1.5, 2.0, 2.5, 3.0, 5.0, 10.0, 15.0, 20.0 or 25.0 microns. In some embodiments, the average longest dimension of the CIGS/Se microparticles is less than the average thickness of annealed film. In some embodiments, the average longest dimension of the CIGS/Se microparticles is less than the average thickness of the annealed film, and the Ra of the annealed film is less than about 1 micron, 0.9 micron, 0.8 micron, 0.7 micron, 0.6 micron, 0.5 micron, 0.4 micron, 0.3 micron, 0.2 micron, 0.1 micron, 0.075 micron, or 0.05 micron, as measured by profilometry. In some embodiments, the average longest dimension of the CIGS/Se microparticles is greater than the average thickness of the annealed film.

It has been found that CIGS—Se can be formed in high yield during the annealing step, as determined by XRD or x-ray absorption spectroscopy (XAS). In some embodiments, the annealed film consists essentially of CIGS—Se, according to XRD analysis or XAS. In some embodiments, at least about 90%, 95%, 96%, 97%, 98%, 99% or 100% of the copper is present as CIGS/Se in the annealed film, as determined by XAS. This film can be further characterized by: at least about 80%, 85%, 90%, 95%, 96%, 97%, 98%, 99% or 100% of the indium is present as CIGS/Se, as determined by XAS.

Coating and Film Thickness.

By varying the ink concentration and/or coating technique and temperature, layers of varying thickness can be coated in a single coating step. In some embodiments, the coating thickness can be increased by repeating the coating and drying steps. These multiple coatings can be conducted with the same ink or with different inks. As described above, wherein two or more inks are mixed, the coating of multiple layers with different inks can be used to fine-tune stoichiometry and purity of the CIGS/Se films. It can also be used to tune the absorption of the film, e.g., by creating films with gradient CIGS/Se compositions. Soft-bake and annealing steps can be carried out between the coating of multiple layers. In these instances, the coating of multiple layers with different inks can be used to create gradient layers, such as layers that vary in the S/Se ratio. The coating of multiple layers can also be used to fill in voids in the at least one layer and planarize or create an underlayer to the at least one layer, as described above.

The annealed film typically has an increased density and/or reduced thickness versus that of the wet precursor layer. In some embodiments, the film thicknesses of the dried and annealed coatings are 0.1-200 microns; 0.1-100 microns; 0.1-50 microns; 0.1-25 microns; 0.1-10 microns; 0.1-5 microns; 0.1-3 microns; 0.3-3 microns; or 0.5-2 microns.

Purification of Coated Layers and Films.

Application of multiple coatings, washing the coating, and/or exchanging capping agents can serve to reduce carbon-based impurities in the coatings and films. For example, after an initial coating, the coated substrate can be dried and then a second coating can be applied and coated by spin-coating. The spin-coating step can wash organics out of the first coating. Alternatively, the coated film can be soaked in a solvent and then spun to wash out the organics. Examples of useful solvents for removing organics in the coatings include alcohols, e.g., methanol or ethanol, and hydrocarbons, e.g., toluene. As another example, dip-coating the substrate into the ink can be alternated with dip-coating the coated substrate into a bath to remove impurities and capping agents. Removal of non-volatile capping agents from the coating can be further facilitated by exchanging these capping agents with volatile capping agents. For example, the volatile capping agent can be used as the washing solution or as a component in a bath. In some embodiments, a layer of a coated substrate comprising a first capping agent is contacted with a second capping agent, thereby replacing the first capping agent with the second capping agent to form a second coated substrate. Advantages of this method include film densification along with lower levels of carbon-based impurities in the film, particularly if and when it is later annealed. Alternatively, binary sulfides and other impurities can be removed by etching the annealed film using standard techniques for CIGS/Se films.

### Preparation of Devices, Including Thin-Film Photovoltaic Cells

Another aspect of this invention is a photovoltaic device comprising a film, wherein the film comprises:
(a) an inorganic matrix; and
(b) CIGS/Se microparticles characterized by an average longest dimension of 0.5-200 microns, wherein the microparticles are embedded in the inorganic matrix.

Another aspect of this invention is a process for preparing a photovoltaic cell comprising a film comprising CIGS/Se microparticles characterized by an average longest dimension of 0.5-200 microns, wherein the microparticles are embedded in an inorganic matrix.

Various embodiments of the film are the same as described above. In some embodiments, the film is the absorber or buffer layer of a photovoltaic cell.

Various electrical elements can be formed, at least in part, by the use of the inks and processes described herein. One aspect of this invention provides a process for making an electronic device and comprises depositing one or more layers in layered sequence onto the annealed coating of the substrate. The layers can be selected from the group consisting of: conductors, semiconductors, and insulators.

Another aspect of this invention provides a process for manufacturing thin-film photovoltaic cells comprising CIGS/Se. A typical photovoltaic cell includes a substrate, a back contact layer (e.g., molybdenum), an absorber layer (also referred to as the first semiconductor layer), a buffer layer (also referred to as the second semiconductor layer), and a top contact layer. The photovoltaic cell can also include an electrode pad on the top contact layer, and an anti-reflective (AR) coating on the front (light-facing) surface of the substrate to enhance the transmission of light into the semiconductor layer. The buffer layer, top contact layer, electrode pads and antireflective layer can be deposited onto the annealed CIGS/Se film in layered sequence.

In one embodiment, the process provides a photovoltaic device and comprises depositing the following layers in layered sequence onto the annealed coating of the substrate having an electrically conductive layer present: (i) a buffer layer; (ii) a transparent top contact layer, and (iii) optionally, an antireflective layer. In yet another embodiment, the process provides a photovoltaic device and comprises disposing one or more layers selected from the group consisting of buffer layers, top contact layers, electrode pads, and antireflective layers onto the annealed CIGS/Se film. In some embodiments, construction and materials for these layers are analogous to those known in the art for a CIGS photovoltaic cell. Suitable substrate materials for the photovoltaic cell substrate are as described above.

### Industrial Utility

Advantages of the inks of the present invention are numerous:

The copper, indium- and gallium-containing elemental and chalcogenide particles are easily prepared and, in some cases, commercially available.

Combinations of the vehicle, CIGS/Se microparticles, elemental and chalcogenide particles, particularly nanoparticles, can be prepared that form stable dispersions while keeping the amount of dispersing agent in the ink at a minimum.

The incorporation of elemental particles in the ink can minimize cracks and pinholes in the films and lead to the formation of annealed CIGS/Se films with large grain size.

The overall ratios of copper, indium, gallium, and chalcogenide in the precursor ink, as well as the sulfur/selenium ratio, can be easily varied to achieve optimum performance of the photovoltaic cell.

The use of nanoparticles enables lower annealing temperatures and denser film packing, while the incorporation of microparticles enables the inclusion of larger grain sizes in the film, even with relatively low annealing temperatures.

The ink can be prepared and deposited using a small number of operations and scalable, inexpensive processes.

Coatings derived from the ink described herein can be annealed at atmospheric pressure. Moreover, for certain ink compositions, only an inert atmosphere is required. For other ink compositions, the use of H₂S or H₂Se is not required to form CIGS/Se, since sulfurization or selenization can be achieved with sulfur or selenium vapor.

In some instances, the film of the present invention comprises CIGS/Se microparticles embedded in an inorganic matrix. Solar cells made from these CIGS/Se layers potentially have all of the advantages of monograin layer solar cells, while incorporating an inorganic matrix with potentially greater heat and light stability as compared to the organic matrix of traditional monograin solar cells. Another advantage is that films of the present invention are less prone to cracking.

### Characterization

Useful analytical techniques for characterizing the composition, size, size distribution, density, and crystallinity of the metal chalcogenide nanoparticles, crystalline multinary-metal chalcogenide particles and layers of the present invention include XRD, XAFS (XAS), EDAX, ICP-MS, DLS, AFM, SEM, TEM, ESC, and SAX.

The following is a list of abbreviations and trade names used above and in the Examples:

| Abbreviation | Description |
|---|---|
| XRD | X-Ray Diffraction |
| TEM | Transmission Electron Microscopy |
| ICP-MS | Inductively Coupled Plasma Mass Spectrometry |
| AFM | Atomic Force Microscopy |
| DLS | Dynamic Light Scattering |
| SEM | Scanning Electron Microscopy |
| SAX | Small Angle X-ray Scattering |
| EDX | Energy-Dispersive X-ray Spectroscopy |
| XAFS | X-Ray Absorption Fine Structure |
| CIGS/Se | Copper-Indium-Gallium-Sulfo-di-selenide |
| Ex | Example |
| RTA | Rapid Thermal Annealing |
| TEA | Triethanolamine |
| TAA | Thioacetamide |

### EXAMPLES

### General

Materials.

Anhydrous solvents are used for the preparation of all formulations and for all cleaning procedures carried out within the drybox.

Solvents are either purchased as anhydrous materials, or are purified by standard methods (e.g., Pangborn, A. G., et al., Organometallics, 1996, 15, 1518-1520) and then stored in the drybox over activated molecular sieves.

Formulation and Coating Preparations.

Substrates (SLG slides) are cleaned sequentially with aqua regia, Miilipore® water and isopropanol, dried at 110° C., and coated on the non-float surface of the SLG substrate. All formulations and coatings are prepared in a nitrogen-purged drybox. Coatings are dried in the drybox.

Annealing of Coated Substrates in a Tube Furnace.

Annealings are carried out either under an inert atmosphere (nitrogen or argon) or under an inert atmosphere comprising a chalcogen source (nitrogen/sulfur or argon/sulfur or nitrogen/selenium). Annealings are carried out in either a single-zone Lindberg/Blue tube furnace (Ashville, N.C.) equipped with an external temperature controller and a one-inch quartz tube, or in a Lindberg/Blue three-zone tube furnace (Model STF55346C) equipped with a three-inch quartz tube. A gas inlet and outlet are located at opposite ends of the tube, and the tube is purged with nitrogen or argon while heating and cooling. The coated substrates are placed on quartz plates inside of the tube.

When annealing under sulfur, a 3-inch long ceramic boat is loaded with 2.5 g of elemental sulfur and placed near the gas inlet, outside of the direct heating zone. The coated substrates are placed on quartz plates inside the tube.

Prior to selenization, samples are first annealed under a nitrogen-purge in the three-inch tube in the three-zone furnace. Then, the samples are placed in a 5″×1.4″×1″ graphite box with 1/8″ walls that is equipped with a lid with a lip and a 1 mm hole in the center. Each graphite box is equipped with two ceramic boats (0.984″×0.591″×0.197″) at each end, containing 0.1 g of selenium. The graphite box is then place in a two-inch tube, with up to two graphite boxes per tube. House vacuum is applied to the tube for 10-15 min, followed by a nitrogen purge for 10-15 min. This process is carried out three times. The tube containing the graphite boxes is then heated in the single-zone furnace with both heating and cooling carried out under a nitrogen purge.

### Particles

CISe Microcrystals. CISe microcrystals are prepared from Cu—In alloy and Se molten fluxes at a growth temperature of 800-1025° K. In some instances, the crystals are ground to provide a fine powder and sieved through a 345 micron mesh to provide sieved microcrystals. In some instances, the crystals are media-milled to provide media-milled microcrystals.

Aqueous Synthesis of CIS Particles.

Aqueous stock solutions were prepared in nanopure water. Solutions of CuSO₄ (2.0 mmol, 0.4 M) and InCl₃(1.0 mmol, 0.4 M) were mixed together in a round bottom flask equipped with a stir bar. Next, solutions of NH₄NO₃ (1 mmol, 0.4 M) and triethanolamine (TEA, 4 mmol, 3.7 M) were sequentially added to the reaction mixture. Sulfuric acid was used to adjust the pH to 1, and the reaction mixture was stirred for 30 min, followed by the addition of aqueous thioacetamide (TAA, 20 mmol, 0.4 M). The flask was placed in a hot water bath with magnetic stirring and the reaction temperature was maintained at 80° C. for 2.5 h to provide a black suspension. Next, the water bath was removed, and the flask was allowed to cool to room temperature. The resulting precipitate was collected via decantation/centrifugation. The solids were washed three times with water. The water-washed solids were dried overnight in a vacuum oven at 45° C. to provide a black powder (the as-synthesized nanoparticles). The nanoparticles were heated at 550° C. under nitrogen for 3 h to provide high purity copper indium sulfide particles (CuInS₂), as indicated by XRD.

CISe Nanoparticles and CIGSe Nanoparticles.

CISe nanoparticles (20-40 nm or 100 nm) and CIGSe nanoparticles (20-40 nm or 100 nm) are used as received from American Elements (Los Angeles, Calif.).

Coated CISe Nanoparticles and Coated CIGSe Nanoparticles.

Coated nanoparticles (5 nm) are used as received from Nanoco (Manchester, UK).

### Synthesis of CuS Nanoparticles

A solution of copper (II) chloride (1.3445 g, 10 mmol) and trioctylphosphine oxide (11.6 g, 30 mmol) in 40 mL of oleylamine was heated at 220° C. under a nitrogen atmosphere with continuous mechanical stirring for 1 h, followed by rapid addition of a solution of sulfur (0.3840 g, 12 mmol) in 10 mL of oleylamine. The reaction mixture was maintained at 220° C. for 2 min, and then cooled in an ice-water bath. Hexane (30 mL) was added to the reaction mixture to disperse the nanoparticles. Then, 60 mL of ethanol was added to the mixture to precipitate the nanoparticles. The nanoparticles were collected by centrifuging the mixture and decanting the supernatant, and then the CuS nanoparticles were dried in a vacuum desiccator overnight. The CuS covellite structure was determined by XRD.

### Synthesis of Cu₂S Nanoparticles

A solution of copper nitrate (Cu(NO₃)₂.2.5H₂O, 0.2299 g, 1 mmol), sodium acetate (0.8203 g, 10 mmol), and glacial acetic acid (0.6 mL) in 20 mL of water was mixed with 1-dodecanethiol (3 mL) at room temperature, in a 400 mL glass-lined Hastelloy C shaker tube. The reaction mixture was heated at 200° C. under 250 psig of nitrogen for 6 h. The reaction mixture was cooled, and the colorless aqueous phase at the bottom of the tube was discarded. Ethanol (20 mL) was added to the dark brown oil phase to precipitate the coated nanoparticles, which were collected via centrifugation. According to XRD and TEM, the coated Cu₂S nanoparticles are roughly spherical, with an average diameter of 10-15 nm.

Purified Cu Nanoparticles.

Commercial copper nanopowder (99.8%, 1 g, 78 nm, Nanostructured & Amorphous Materials, Inc., Houston, Tex.) was added to a solution containing 10 g citric acid, 1.5 g L-ascorbic acid, 1 mL Citranox (Alconox Inc., White Plains, N.Y.) and 20 mL water. The mixture was sonicated in a bath sonicator at 50° C. for 30 min. The copper nanoparticles were collected by centrifuging and decanting the supernatant. Next, the Cu nanoparticles were washed twice with water and once with ethanol, and then dried in a vacuum desiccator overnight.

Indium Nanoparticles.

Indium nanoparticles (20-40 nm or 100 nm) are used as received from American Elements (Los Angeles, Calif.).

Sulfur Power.

Sulfur powder (sublimed, 99.5%) was purchased from Alfa Aesar.

### Prophetic Example 1

This example illustrates the preparation of an ink in which the CISe microcrystals have a different composition than the CIS matrix. The ink is formed from sieved CISe microcrystals, purified copper nanoparticles, and indium nanoparticles, prepared or purchased as described above. The coated substrate is annealed under a sulfur-containing atmosphere.

### Example 1

Cu nanoparticles (37.5 mg, 0.590 mmol), In nanoparticles (67.7 mg, 0.590 mmol), and sieved CISe₂ microcrystals (200 mg, 0.592 mmol) are combined in 1 mL of THF The mixture is then sonicated in a bath sonicator for 20 min. This ink is agitated strongly immediately prior to drop-coating a portion of it onto a Mo-coated glass substrate located on a room-temperature hotplate. After allowing the THF to evaporate, the temperature of the hotplate is raised to 170° C., kept at temperature for 15 min, and then allowed to cool to room temperature. The coated substrate is annealed in a 3-inch tube furnace at 500° C. for 1 h under N₂, and is then annealed at 500° C. for 0.5 hr in a 1-inch tube furnace under a sulfur/N₂ atmosphere. The annealed sample is etched in a 0.5 M KCN solution at 50° C. for 1 min, rinsed with deionized water, and dried under a nitrogen stream.

### Prophetic Example 2

Examples 2A-2J provide demonstrations of different annealing atmospheres and conditions, and variations wherein the ink of Example 1 comprises sulfur powder, Cu sulfide nanoparticles, CISe nanoparticles, CIGSe nanoparticles, coated CISe nanoparticles, coated CIGSe nanoparticles, CIS particles prepared by an aqueous route, and media-milled CISe microcrystals.

### Example 2A

Example 1 is repeated except that sulfur powder (37.8 mg, 1.18 mmol) is added to the mixture prior to sonication and the second annealing under sulfur is omitted. The first annealing is modified as follows: the coated substrate is annealed under an argon atmosphere in a 3-inch tube. The temperature is raised to 250° C. at a rate of 15° C./min and then raised to 500° C. at a rate of 2° C./min. The temperature is to held at 500° C. for 1 h before allowing the tube to cool to room temperature.

### Example 2B

Example 1 is repeated with the replacement of the Cu nanoparticles by 0.590 mmol of CuS nanoparticles.

### Example 2C

Example 1 is repeated with the replacement of the Cu nanoparticles by 0.590 mmol of Cu₂S nanoparticles and the addition of sulfur powder (37.8 mg, 1.18 mmol) to the ink. The second annealing under sulfur is omitted. The first annealing is modified as described in Example 2A.

### Example 2D

Example 1 is repeated with the replacement of the Cu and In nanoparticles by 0.590 mmol of 100 nm CIGSe nanoparticles and the second annealing is carried out under a selenium/nitrogen atmosphere.

### Example 2E

Example 1 is repeated with the replacement of the Cu and In nanoparticles by 0.590 mmol of 100 nm CISe nanoparticles and the second annealing under sulfur is omitted. The first annealing is modified as described in Example 2A.

### Example 2F

Example 1 is repeated with the replacement of the Cu and In nanoparticles by 0.590 mmol of 5 nm coated CIGSe nanoparticles and the second annealing is carried out under a selenium/nitrogen atmosphere.

### Example 2G

Example 1 is repeated with the replacement of the Cu and In nanoparticles by 0.590 mmol of 5 nm, coated CISe nanoparticles and the second annealing under sulfur is omitted. The first annealing is modified as described in Example 2A.

### Example 2H

Example 1 is repeated with the replacement of the Cu and In nanoparticles by 0.590 mmol of 5 nm, coated CISe nanoparticles and the addition of 0.1 g of CIS particles, prepared by an aqueous synthesis as described above, to the ink.

### Example 2I

Example 1 is repeated with the replacement of the 0.2 g of sieved CISe microcrystals by 0.1 g of media-milled CISe microcrystals and 0.1 g of CIS particles, prepared by the aqueous route. The second annealing is carried out under a selenium/nitrogen atmosphere for 15 min.

### Example 2J

Example 1 is repeated with the exception that the second annealing is carried out under a selenium/nitrogen atmosphere.

What is claimed is:

1. An ink comprising:
(a) a plurality of CIGS/Se microparticles;
(b) a plurality of particles selected from the group consisting of:
CIGS/Se nanoparticles; elemental Cu-, In-, or Ga-containing particles; binary or ternary Cu-, In-, or Ga-containing chalcogenide particles; and mixtures thereof; and
(c) a vehicle.

2. The ink of claim 1, wherein the vehicle and at least one of (a) the plurality of CIGS/Se microparticles and (b) the plurality of particles have been heat processed at a temperature of greater than about 90° C.

3. The ink of claim 1, wherein the molar ratio of Cu:(In+Ga) is about 1 in the ink.

4. The ink of claim 1, wherein the plurality of particles comprises CIGS/Se nanoparticles or binary or ternary Cu-, In-, or Ga-containing chalcogenide particles, or the ink further comprises an elemental chalcogen.

5. The ink of claim 4, wherein the chalcogenide particles are selected from the group consisting of: sulfide particles, selenide particles, sulfide/selenide particles, and mixtures thereof; and the elemental chalcogen is sulfur, selenium, or a mixture thereof.

6. The ink of claim 4, wherein the molar ratio of total chalcogen to (Cu+In+Ga) is at least about 1.

7. The ink of claim 1, wherein the plurality of particles comprises nanoparticles having an average longest dimension of less than about 0.5 micron, as determined by electron microscopy.

8. The ink of claim 1, wherein the elemental Cu-, In-, or Ga-containing particles are selected from the group consisting of: Cu particles, Cu—In alloy particles, Cu—Ga alloy particles, Cu—In—Ga alloy particles, In particles, In—Ga alloy particles, Ga particles; and mixtures thereof; and the binary or ternary Cu-, In-, or Ga-containing chalcogenide particles are selected from the group consisting of: Cu₂S/Se particles, CuS/Se particles, In₂(S,Se)₃ particles, InS/Se particles, Ga₂(S,Se)₃ particles, GaS/Se particles, (Ga,In)₂(S,Se)₃ particles, and mixtures thereof.

9. A coated substrate comprising:
(a) a substrate; and
(b) at least one layer disposed on the substrate comprising:
(i) a plurality of CIGS/Se microparticles; and
(ii) a plurality of particles selected from the group consisting of:
CIGS/Se nanoparticles; elemental Cu-, In-, or Ga-containing particles; binary or ternary Cu-, In-, or Ga-containing chalcogenide particles; and mixtures thereof.

10. The coated substrate of claim 9, wherein the molar ratio of Cu:(In+Ga) is about 1 in the at least one layer.

11. The coated substrate of claim 9, wherein the plurality of particles comprises CIGS/Se nanoparticles or binary or ternary Cu-, In-, or Ga-containing chalcogenide particles, or the at least one layer further comprises an elemental chalcogen.

12. The coated substrate of claim 11, wherein the molar ratio of total chalcogen to (Cu+In+Ga) is at least about 1.

13. The coated substrate of claim 9, wherein the elemental Cu-, In-, or Ga-containing particles are selected from the group consisting of: Cu particles, Cu—In alloy particles, Cu—Ga alloy particles, Cu—In—Ga alloy particles, In particles, In—Ga alloy particles, Ga particles; and mixtures thereof; and the binary or ternary Cu-, In-, or Ga-containing chalcogenide particles are selected from the group consisting of: Cu₂S/Se particles, CuS/Se particles, In₂(S,Se)₃ particles, InS/Se particles, Ga₂(S,Se)₃ particles, GaS/Se particles, (Ga,In)₂(S,Se)₃ particles, and mixtures thereof.

14. A process comprising disposing an ink onto a substrate to form a coated substrate, wherein the ink comprises:
(a) a plurality of CIGS/Se microparticles;
(b) a plurality of particles selected from the group consisting of:
CIGS/Se nanoparticles; elemental Cu-, In-, or Ga-containing particles; binary or ternary Cu-, In-, or Ga-containing chalcogenide particles; and mixtures thereof; and
(c) a vehicle.

15. A film comprising:
(a) an inorganic matrix; and
(b) CIGS/Se microparticles characterized by an average longest dimension of 0.5-200 microns, wherein the microparticles are embedded in the inorganic matrix.
